(19) United States
(12) Patent Application Publication
(10) Pub. No.: US 2026/0238189 A1
(43) Pub. Date: Aug. 13, 2026

(54) SUBSTRATE-MOUNTED INTEGRATED STRUCTURE COMPRISING A FERROELECTRIC LAYER WITH SELECTIVE POLARISATION, AND METHOD FOR MANUFACTURING SAME

(71) Applicant: Soitec, BERNIN (FR)

(72) Inventors: Alexis Drouin, BERNIN (FR); Sébastien Ledrappier, BERNIN (FR)

(21) Appl. No.: 19/149,124

(22) PCT Filed: Jan. 29, 2024
(86) PCT No.: PCT/EP2024/052092

§ 371 Date: Jul. 18, 2025

(30) Foreign Application Priority Data
Feb. 9, 2023 (FR) FR2301220

(51) Int. Cl. H03H 9/25; H03H 3/10; H03H 9/02

(52) U.S. Cl. CPC H03H 9/25; H03H 3/10; H03H 9/02559; H03H 9/02574

(57) ABSTRACT

A structure includes a ferroelectric layer having a first polarization in a first area and a second polarization, opposite to the first polarization, in a second area different from the first area. The first polarization and the second polarization are oriented perpendicularly or obliquely to the ferroelectric layer. The second polarization area has a hydrogen concentration greater than the first polarization area. The structure further includes a support and a dielectric layer disposed between the support and the ferroelectric layer.

### CROSS-REFERENCE TO RELATED APPLICATIONS

This application is a national phase entry under 35 U.S.C. § 371 of International Patent Application PCT/EP2024/052092, filed Jan. 29, 2024, designating the United States of America and published as International Patent Publication WO 2024/165363 A1 on Aug. 15, 2024, which claims the benefit under Article 8 of the Patent Cooperation Treaty of French Patent Application Serial No. FR2301220, filed Feb. 9, 2023.

### TECHNICAL FIELD

The disclosure relates to an integrated structure comprising a ferroelectric layer attached to a carrier by way of a dielectric layer, and to a method for manufacturing this structure. Such a structure can be used to form non-linear optical components or radiofrequency (RF) components, in particular surface elastic wave components.

### BACKGROUND

Several applications exist that leverage, or are influenced by, the polarization properties of ferroelectric materials and the presence of polarization domains that are opposite each other. These include non-linear optics with, for example, devices, called frequency doublers, that allow an electromagnetic wave to be generated with twice the frequency as that sent to the input of the device, by way of a periodically polarized ferroelectric crystal. Surface acoustic wave (SAW) devices also can be cited. The existence of these applications has led to the development of methods for controlling the polarization domains of the ferroelectric layers.

The article entitled, “Seeing Is Believing”-In-Depth Analysis by Co-Imaging of Periodically-Poled X-Cut Lithium Niobate Thin Films,” by Sven Reitzig et al., published in Crystals 2021, 11, 288, describes a lithium niobate layer integrated on a silicon substrate by way of a silica layer, and controlling the polarization of this layer parallel to the plane in which it extends, by applying a voltage between electrodes periodically disposed on the free surface of the layer. It should be noted that, in such a structure that only comprises electrodes on the sole free face of the crystal, controlling a polarization that would be perpendicular to the substrate by way of an electric field, in the absence of an embedded electrode, would require voltages that risk causing the silica layer to breakdown.

Document EP 0592226 A1 describes an optical frequency conversion device obtained by the periodic juxtaposition of parallel strips of inverted polarization on a face of a ferroelectric substrate having a spontaneous polarization perpendicular to the plane of extension of the substrate, i.e., perpendicular to this face. Polarization inversion by strips is obtained by carrying out a proton exchange through a mask.

Document WO 2005/052682 A1 describes the localized inversion of the polarization of a ferroelectric crystal with spontaneous polarization perpendicular to one of its faces, by applying an electric field along juxtaposed periodic strips, by way of gel electrodes placed on this face and the face opposite the crystal.

The structures and methods described above, although they effectively allow the polarization domains of a ferroelectric layer to be controlled, remain impractical and do not allow effective and safe control of a polarization perpendicular to a face of a ferroelectric crystal, and even less so that of a ferroelectric layer integrated on a carrier.

### BRIEF SUMMARY

A first aim of the disclosure is to provide a ferroelectric layer in a form that is integrated on a substrate, with polarization having polarization domains with orientations that are opposite and perpendicular or oblique with respect to the plane of this layer and are able to be used with a view to applications based on non-linear optics or bulk acoustic waves, for example. A second aim of the disclosure is a manufacturing method for obtaining the aforementioned integrated ferroelectric layer. A third aim of the disclosure is a method for the local and controlled inversion of the polarization of any ferroelectric element.

In order to achieve these objectives, a first aspect of the disclosure is a structure comprising a ferroelectric layer having a first polarization in a first zone and a second polarization, opposite the first polarization, in a second zone distinct from the first zone, wherein the first polarization and the second polarization are oriented perpendicularly or obliquely to the ferroelectric layer, the second polarization zone has a higher hydrogen concentration than the first polarization zone, the structure further comprising a carrier and a dielectric layer interposed between this carrier and the ferroelectric layer.

An advantage of the structure according to the disclosure is the provision of an integrated structure, including a substrate, on which a ferroelectric layer is attached having at least two distinct polarizations perpendicular or oblique with respect to the planes of extension of the layer and of the substrate. Such a structure facilitates the integration of non-linear optical or surface acoustic functions, while keeping costs low.

According to additional non-limiting features of the first aspect of the disclosure, considered individually or according to any technically feasible combination:
a hydrogen density in the second zone (V) can range between 10¹⁹ and 10²²atoms/cm³;
the first zone and the second zone can define periodic patterns;
the ferroelectric layer can be formed by a single crystal;
the ferroelectric layer can comprise lithium niobate or lithium tantalate;
the dielectric layer can comprise silicon oxide;
the carrier can comprise single-crystal silicon.

A second aspect of the disclosure relates to a method for manufacturing a structure for which the polarization is locally controlled, comprising the steps of providing a ferroelectric element having a first polarization; selectively enriching the ferroelectric element with hydrogen ions through a face of the ferroelectric element; and annealing the ferroelectric element after introducing the hydrogen ions, at a temperature ranging between 400° C. and 700° C., so as to switch the polarization of the ferroelectric layer in a volume defined by the selective introduction of the hydrogen ions.

The method according to the disclosure is advantageous in that it is simple, flexible and can be easily integrated into a broader manufacturing method based on known and proven manufacturing techniques from the semiconductor industry. In addition, it allows local control of the polarization of a ferroelectric element for which a single face is accessible and is therefore applicable to thin layers integrated on a substrate.

According to additional non-limiting features of the second aspect of the disclosure, considered individually or according to any technically feasible combination:
the polarization can be mono-domain, perpendicular or oblique with respect to a face of the ferroelectric element;
the selective enrichment of the hydrogen ions can be implemented by ion implantation of the hydrogen ions through a mask defining a region of the ferroelectric element not receiving hydrogen ions;
the hydrogen ion implantation is at an energy level ranging between 3 keV and 210 keV;
the selective introduction of the hydrogen ions can be provided by elements intended to form part of a surface acoustic wave device;
the ferroelectric element can be a lithium niobate or lithium tantalate layer;
the method can further comprise assembling a ferroelectric substrate and a carrier, followed by separating or thinning the ferroelectric substrate so as to define the ferroelectric element;
the carrier can be a single-crystal silicon substrate, and a dielectric layer comprising silicon oxide is interposed between this single-crystal silicon substrate and the ferroelectric substrate; and
a dose of the selective enrichment of the ferroelectric element with hydrogen ions (H⁺) can be adapted so as to obtain a hydrogen density ranging between 10¹⁹ and 10²² atoms/cm³ in the volume (V).

### BRIEF DESCRIPTION OF THE DRAWINGS

Further features and advantages of the disclosure will become apparent from the following detailed description of the disclosure, with reference to the accompanying figures, in which:

FIG. 1 shows a ferroelectric element with selectively modified polarization and a corresponding manufacturing method according to the present description;

FIG. 2 shows alternative embodiments of the ferroelectric element of FIG. 1;

FIG. 3 shows an alternative embodiment of the ferroelectric element of FIG. 1;

FIG. 4 illustrates a first method for integrating a ferroelectric layer on a carrier;

FIG. 5 illustrates a second method for integrating a ferroelectric layer on a carrier;

FIG. 6 is a schematic plan view of a device according to the present description;

FIG. 7 is a schematic cross-sectional view of the device of FIG. 6.

### DETAILED DESCRIPTION

### Selective Polarization Inversion

Following a series of experiments, the applicant has realized that it is possible to switch the polarization of polarization domains by hydrogen implantation followed by annealing. These experimental results are implemented in the manufacturing method described hereafter, resulting in a ferroelectric element 10 having polarization domains with geometries selected by the practitioner.

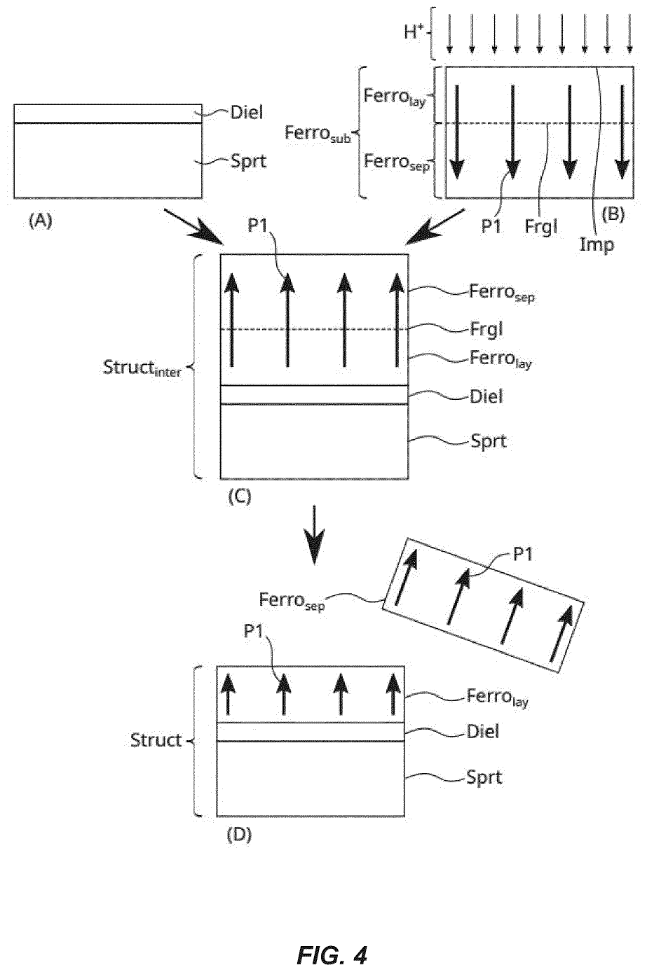

The ferroelectric element 10 can be a ferroelectric single-crystal as such, this single-crystal can be in the form of a ferroelectric single-crystal layer, this ferroelectric crystal or this ferroelectric single-crystal layer can be attached to a carrier Sprt within a structure Struct, such as the ferroelectric layer Ferro_{lay} illustrated in section (D) of FIG. 4.

FIGS. 1 and 3 illustrate a first embodiment, in which the ferroelectric element 10 is a ferroelectric single-crystal as such, i.e., without being attached to a carrier.

Section (A) of FIG. 1 shows a cross-section, in a plane ZX, of the ferroelectric element 10 having two opposite faces Sup and Inf perpendicular to a direction Z and having a first single-domain polarization P1 parallel to the direction Z and perpendicular to the upper Sup and lower Inf faces parallel to the plane of extension of the ferroelectric element 10, i.e., the crystalline plane in which its dimensions are largest.

For explanatory purposes, this embodiment uses the example of a polarization perpendicular to the plane of extension of the ferroelectric element 10. However, the disclosure also applies to the situation where the polarization is not perpendicular to the plane of extension of the ferroelectric element 10 but is oblique thereto. The “perpendicular” feature refers to an incline of 90° relative to the plane of extension of the ferroelectric element to the nearest 10°, the “oblique” or “obliquely” feature refers to an incline at least 5° away from the plane of extension of the ferroelectric element. A direction with an incline within the range ranging from 5° to 80°, or from 30° to 70°, or even from 35° to 60°, thus can be considered to be oblique. For example, a layer of LiTaO₃50RY and a layer of LiTaO₃42RY have polarizations inclined at 50° and 42°, respectively, relative to the plane of extension of the layer, and therefore have oblique polarizations relative to the plane of extension of the layer.

In a step S10, the ferroelectric element 10 is selectively enriched with hydrogen by selective ion implantation of hydrogen ions H⁺, at an implantation energy level ranging between 3 keV and 210 keV. As illustrated in section (B) of FIG. 1, the selectivity of the implantation can be provided by forming a mask M using a conventional lithography method, which mask is made of resin, metal, oxide, nitride or any other material capable of stopping the hydrogen ions during implantation, so that the regions of the ferroelectric element covered by the mask do not receive hydrogen. For practical applications, the pattern formed by the mask M can be made up of a periodic pattern, for example, made up of strips of the same width that are parallel to each other and are constantly spaced apart, as illustrated in section (B_{P}) as a top view in the YX plane. Following implantation, the mask M is removed in this example.

This step results in the formation of relatively hydrogen-rich volumes V in the ferroelectric element 10, with a surface coverage corresponding to the negative of the pattern of the mask M and a depth depending on the acceleration energy of the implantation step. The volumes V thus form a periodic pattern in a direction within a plane parallel to the plane of extension of the ferroelectric element 10, i.e., in a direction within an outer surface of the ferroelectric element 10. The implantation dose is adapted to the implantation energy so as to obtain a hydrogen density ranging between 10¹⁹ and 10²² atoms/cm³ in the volumes V. It is also possible to carry out several successive implantations at different implantation energy levels in order to better define the volumes V and by homogenizing the distribution of the implanted hydrogen. At this stage, the polarization of the entire ferroelectric element 10 remains unchanged in the implanted zones, with the implanted zones and the non-implanted zones still forming a single mono-domain in which the polarization has only one orientation.

In the present document, the YX and ZX planes are defined by the X, Y, Z axes of an orthogonal reference frame, with the YX plane being defined by the Y and X axes of the reference frame, the ZX plane being defined by the Z and X axes of the reference frame. The faces Sup and Inf of the ferroelectric element 10 extend parallel to the YX plane, perpendicular to the Z axis, which defines the thickness of the ferroelectric element 10. In addition, selective implantation or selective enrichment is understood to mean implantation or enrichment in certain regions of the ferroelectric element 10, selected by the practitioner and in this case defined by the pattern of the mask M.

In a step S20, the ferroelectric element 10 selectively enriched with hydrogen is annealed at a temperature ranging between 400° C. and 800° C., preferably between 500° C. and 700° C., more preferably between 550° C. and 600° C. This annealing step causes an inversion of the first polarization P1 of the ferroelectric element 10 only on the hydrogen-enriched volumes V in order to yield a second polarization P2, with the same direction of alignment as the first polarization P1, but in the opposite direction thereto, specific to the hydrogen-enriched volumes V as illustrated in section (C0). Anti-parallel polarizations are defined as polarizations aligned in parallel directions but in opposite directions. Conversely, parallel polarizations are defined as polarizations aligned in parallel directions and in the same direction. Inverting the polarization only at the volumes V results in the transition from a configuration of parallel polarizations between the volumes V and the rest of the ferroelectric element 10 to a configuration of anti-parallel polarizations. Annealing is preferably carried out in an oxygen atmosphere in order to reduce oxygen exodiffusion from the ferroelectric layer, but also can be carried out, for example, in a nitrogen or air atmosphere at atmospheric pressure for a duration ranging between 100 seconds and 10 hours.

The volumes V define a second zone having a second polarization P2 different from, and in fact opposite to, a first polarization P1 of a first zone defined by the volume of ferroelectric material included in the ferroelectric element 10 from which the second zone is removed. Thus, the first and second zones are complementary, with the sum of their parts forming the total volume of the ferroelectric material included in the ferroelectric element 10, i.e., the whole of a ferroelectric crystal when the ferroelectric element 10 is made up of such a crystal. The first zone and the second zone can be formed by disjunct volumes or can even form continuous volumes, depending on the shape given to the selective implantation region and its depth. During the manufacturing method, the second zone is enriched with hydrogen, so that the hydrogen concentration of the second zone is higher than the first zone.

Section (C0_{P}) of FIG. 1 illustrates the state of polarization of the ferroelectric element 10 in the vicinity of the upper face Sup by way of a top view in the YX plane on completion of step S20, with domains with opposite polarizations with geometries defined by the volumes V obtained following the selective hydrogen enrichment by way of the mask M.

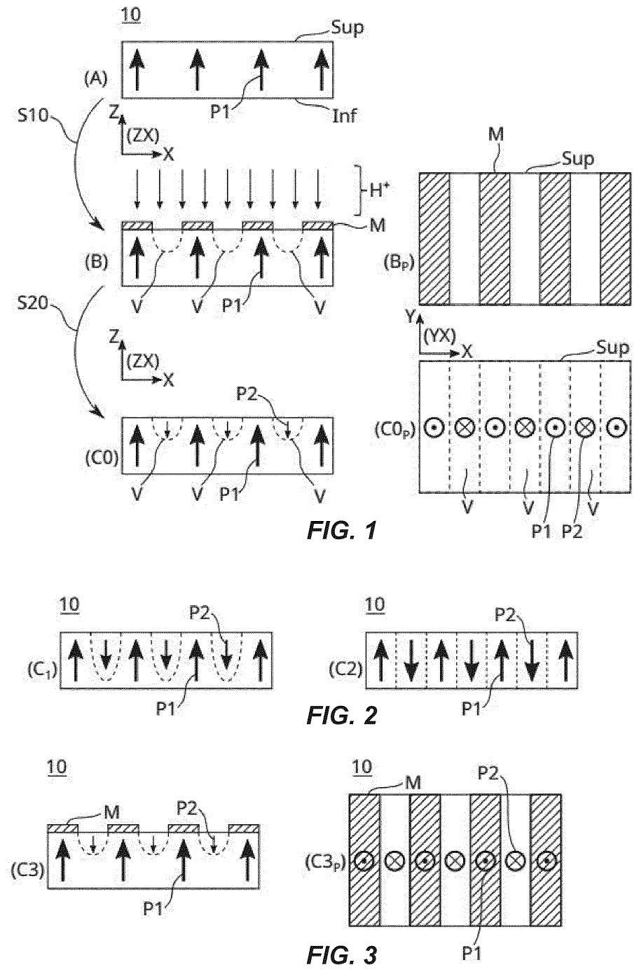

Sections (C1) and (C2) of FIG. 2 illustrate geometries for the volumes V obtained for increasing and higher implantation energy levels than for the geometry illustrated in section (CO). In particular, in section (C2), the polarization inversion is effective over the entire thickness of the crystal, which is achieved by a sufficiently high implantation energy level, depending on the distance between the faces Sup and Inf.

FIG. 3 shows a sectional view (C3) and a plan view (C3_{P}) respectively corresponding to sections (C0) and (C0_{P}), illustrating an alternative embodiment in the method in step S10, in which the mask M is not removed following hydrogen implantation and step S20 is applied while the mask is still present. Polarization inversion in the zones selectively enriched with hydrogen normally occurs in step S20. This alternative embodiment can be used, for example, in the event that it would be desirable to precisely align electrodes with reverse polarization zones. In this case, the hydrogen-enriched zones are self-aligned with the electrodes used as masks for the selective hydrogen enrichment.

The selective polarization inversion method described above is implemented by acting on only one face of the ferroelectric element. This feature therefore offers the possibility of controlling the polarization of a ferroelectric element whose rear face is inaccessible or is too far from the front face, ensuring great flexibility in terms of the application of the method and its applicability to various geometries.

As already mentioned, this first embodiment is illustrative and is not limited to controlling the polarization of a single ferroelectric crystal, but can also be applied to more complex structures, as will become apparent throughout the remainder of this disclosure.

### Integration on a Carrier—Solution 1

The method for selective polarization inversion described above is illustrated in FIGS. 1 to 3 in the situation whereby it is applied to a single ferroelectric crystal, used as the ferroelectric element 10. This method for selective inversion also can be applied to an assembly formed by a ferroelectric crystal integrated on a substrate, which assembly can then form the ferroelectric element 10 illustrated in FIGS. 1 to 3.

The integration on a substrate can be carried out as explained hereafter with reference to FIG. 4, and with reference to publication WO 2020/200986 A1, which particularly describes attaching a thin single-domain ferroelectric layer to a substrate.

FIG. 4 shows a method for manufacturing an integrated structure Struct illustrated in section (D), comprising a ferroelectric layer Ferro_{lay} attached to a carrier Sprt by means of a dielectric layer Diel. The layer Diel is in direct contact with each one from among the carrier Sprt and the ferroelectric layer Ferro_{lay}.

Conventionally, the structure Struct can be in the form of a circular wafer, the diameter of which can be 100, 200, 300 or even 450 mm, but the disclosure is by no means limited to these dimensions or to this shape.

The ferroelectric layer Ferro_{lay} is made up of a single-crystal ferroelectric material, such as lithium tantalate LiTaO₃ or lithium niobate LiNbO₃, or even of materials such as LiAlO₃, BaTiO₃, PbZrTiO₃, KNbO₃, BaZrO₃, CaTiO₃, PbTiO₃ or KTaO₃. These materials also have piezoelectric properties. In general, the thickness of the ferroelectric layer can range between 10 nanometers and 10 microns, depending on the contemplated application of the structure Struct and the expected performance capabilities of the components, but the disclosure does not exclude the use of different thicknesses, still depending on the contemplated application. By way of a reminder, a ferroelectric material is a material that has electric polarization in its natural state, which polarization can be reversed by applying an external electric field that is greater than the coercive field of the material. As illustrated in the present document, the ferroelectric layer preferably has a first single-domain polarization P1, i.e., all the dipole moments are aligned parallel to each other in a given direction. In this case, the given direction is the direction perpendicular to the plane of the ferroelectric layer, i.e., perpendicular to the free face of this layer, or even perpendicular to a surface plane of this layer.

For reasons of availability and cost, the carrier Sprt for its part is preferably selected from silicon. It can be a carrier made up of a solid single-crystal silicon base substrate, but the disclosure is not limited to this carrier, which can, more generally, be made up of any material, for example, silicon, even electrically insulating material such as sapphire or glass. When formed from a solid substrate, the thickness of the carrier Sprt is typically several hundred microns. In a single-crystal silicon, the carrier Sprt is electrically conductive, but preferably has high resistivity, greater than 1,000 ohms. This limits the density of any charges, holes or electrons, which are susceptible to move, which could affect the correct operation of an RF component that would be formed on the basis of the structure Struct. However, the disclosure is not limited to a carrier with such features.

Optionally, the carrier Sprt can be provided with a charge trapping layer, which is a non-single-crystal layer having structural defects such as dislocations, grain boundaries, amorphous zones, interstices, inclusions, pores, etc. These structural defects form traps for the charges liable to flow through the material, for example, at the site of incomplete or pendant chemical bonds. Conduction is thus prevented in the trapping layer, which consequently has a high resistivity. Its thickness, notably when it is formed on a resistive carrier, can range between 0.1 and 3 μm. However, other thicknesses below or above this range are perfectly feasible, depending on the expected performance level of the structure. Advantageously, and for reasons of simplicity of implementation, this trapping layer is formed by a layer of polycrystalline silicon. It can also include layers, or be formed entirely, of a silicon and carbon alloy. When present, this trapping layer is located on the side of the dielectric layer Diel. Other dielectric or electrically conductive layers with functionalities that are considered to be useful by the practitioner depending on the type of applications that are contemplated also can be present, adjacent to the dielectric layer Diel.

For its part, the thickness of the dielectric layer Diel can range between several nanometers and several microns, for example, 5 microns or more. It typically can be formed from an amorphous material, such as silicon oxide, silicon oxynitride or silicon nitride-silicon dioxide. It also can be an oxide such as Ta₂O₅, ZrO₂ or HfO or Al₂O₃.

With reference to FIG. 4, the structure Struct can be produced by a layer attachment manufacturing method comprising:
preparing the carrier Sprt illustrated in section (A);
optionally preparing a ferroelectric donor substrate Ferro_{sub} illustrated in section (B);
assembling, via the dielectric layer Diel, a first face of the carrier Sprt and a face of the ferroelectric donor substrate Ferro_{sub} in order to form an intermediate structure Structᵢₙₜₑᵣ as illustrated in section (C); and
detaching part of the donor substrate Ferro_{sub} from the intermediate structure in order to define the ferroelectric layer Ferro_{lay} on the carrier Sprt and to obtain the structure Struct illustrated in section (D).

The carrier Sprt can be prepared by adding a dielectric layer Diel, as shown in section (A). This dielectric layer can be formed by a stack of different types of dielectric layers selected from the materials listed above, for example. The dielectric layer Diel can be produced directly on the carrier Sprt using various techniques that are known in the prior art, such as thermal oxidation or nitridation treatments, chemical depositions using techniques known as LPCVD (Low Pressure Chemical Vapor Deposition), PECVD (Plasma Enhanced Chemical Vapor Deposition), or even PVD (Physical Vapor Deposition) or ALD (Atomic Layer Deposition).

The donor substrate Ferro_{sub} illustrated in section (B) is a substrate made up of the ferroelectric material of the ferroelectric layer Ferro_{lay}, or comprising a surface thickness of this material. Thus, by way of an example, the donor substrate can be formed by a solid substrate of lithium tantalate or lithium niobate, or even by a composite substrate formed by a first substrate, on which a thickness (at least equal to that of the layer Ferro_{lay}) of lithium tantalate or lithium niobate rests. The donor substrate preferably has a first single-domain polarization P1 perpendicular to the implantation face Imp by which the hydrogen ions are implanted in the donor substrate. This orientation is conventionally achieved by selecting the growth mode of the crystal and its cutting plane.

The ferroelectric layer Ferro_{lay} can be transferred from the ferroelectric donor substrate Ferro_{sub} using Smart Cut™ technology, in which case, the donor substrate must be prepared by introducing light species, such as hydrogen or helium, into the donor substrate. This introduction can correspond to hydrogen implantation, i.e., hydrogen ion bombardment of a flat face Imp of the donor substrate Ferro_{sub}. As is known per se, and as illustrated in section (B), the implanted hydrogen ions H⁺ are intended to form an embrittlement plane Frgl delimiting the ferroelectric layer Ferro_{lay} of ferroelectric material to be transferred that is located on the side of the face Imp and another part Ferroₛₑₚ forming the remainder of the substrate and that will be separated from the ferroelectric layer Ferro_{lay} in a subsequent step.

The type and dose of the implanted species and the implantation energy are selected as a function of the thickness of the layer to be transferred and of the physico-chemical properties of the donor substrate Ferro_{sub}. In the case of a donor substrate made of LiTaO₃, it is possible to choose to implant a dose of hydrogen ranging between 10¹⁶ and 5.1017 at/cm² with an energy level ranging between 30 and 300 keV in order to delimit a ferroelectric layer Ferro_{lay} of the order of 200 to 2,000 nm thick.

Following the preparation of the carrier Sprt and of the donor substrate Ferro_{sub}, these two elements are assembled by bringing the free face of the dielectric layer into contact with the implantation face Imp of the donor substrate so as to obtain the intermediate structure Structᵢₙₜₑᵣ illustrated in section (C) of FIG. 4. The carrier substrate Sprt can have the same size and shape as those of the donor substrate Ferro_{sub}, but the disclosure is not limited to such a configuration and different sizes and shapes can be employed.

Prior to assembly, it is possible to contemplate preparing the faces of the substrates to be assembled by way of a step of cleaning, brushing, drying, polishing or plasma activation.

Assembly can involve bringing the donor substrate Ferro_{sub} into close contact with the carrier Sprt by molecular adhesion and/or electrostatic bonding. One function of the dielectric layer Diel formed on the carrier Sprt is to facilitate assembly. Alternatively, provision can be made for the dielectric layer Diel to be formed on the implantation face Imp of the donor substrate Ferro_{sub}, preferably before the formation of the embrittlement plane Frgl. It is also possible for the dielectric layer Diel to be formed in two parts, respectively on each one from among the carrier and the donor substrate.

As is well known per se, during a molecular adhesion method, the exposed surfaces of the carrier Sprt and of the donor substrate Ferro_{sub} (with one and/or the other being covered with a dielectric layer intended to form the dielectric layer Diel), which are perfectly clean, flat and smooth, are brought into close contact in order to promote the development of molecular bonds, for example, of the Van der Waals or covalent type. The assembly of the two bodies is then achieved without using an adhesive.

Assembly can include applying a low temperature heat treatment (for example, ranging between 50 and 300° C., typically 100° C.) so as to rectify any crystalline defects present in the ferroelectric layer and to sufficiently increase the bonding energy in order to allow an optional subsequent thinning step.

In the present embodiment, the step of detaching part of the donor substrate is carried out by applying Smart Cut™ technology, according to which a layer intended to form the ferroelectric layer Ferro_{lay} is delimited by the embrittlement plane Frgl. After the assembly step, this layer is detached from the donor substrate by fracturing in the vicinity of the embrittlement plane Frgl and is thus attached to the carrier Sprt.

This detachment step can thus include applying a heat treatment to the intermediate structure Structᵢₙₜₑᵣ in a temperature range of the order of 80° C. to 300° C. in order to detach the part of the donor substrate from the ferroelectric layer Ferro_{lay} and transfer it to the carrier substrate Sprt. As an alternative to or in addition to the heat treatment, this step can include applying a blade or a jet of gaseous or liquid fluid, or any other mechanical force, to the embrittlement plane Frgl.

As an alternative to implementing the Smart Cut™ method described above, the step of detaching part of the donor substrate can be replaced by a step of chemical-mechanical thinning of this ferroelectric donor substrate Ferro_{sub}.

Whether the removal of part of the thickness of the donor substrate is carried out by thinning or by fracturing, any type of finishing treatment can be applied to the structure Struct thus formed in order to allow the ferroelectric layer Ferro_{lay} to comply with specifications in terms of thickness, thickness uniformity, roughness, crystalline quality or any other type of specifications.

In particular, with a view to using a ferroelectric layer Ferro_{lay} that would have single-domain polarization, the qualities of the dielectric layer Diel can be guaranteed and a particular treatment can be applied to the ferroelectric layer Ferro_{lay} attached to the substrate Subst, all with the aim of obtaining a single-domain polarization of the ferroelectric layer Ferro_{lay}.

Indeed, assembly can cause hydrogen to accumulate at the interface between the dielectric layer and the ferroelectric layer, forming a gradient of hydrogen concentration allowing the multi-domain transformation of a portion of the ferroelectric layer in contact with the assembly layer during the heat treatment for separating the ferroelectric layer Ferro_{lay} from the ferroelectric substrate Ferro_{sub}.

With respect to the dielectric layer Diel, it is possible to ensure that it has a lower hydrogen concentration than that present in the ferroelectric layer Ferro_{lay}, so that any excess hydrogen in the ferroelectric layer can be absorbed into the dielectric layer during the diffusion caused by the heat treatment for separating the layer Ferroₛₑₚ. This prevents hydrogen from accumulating at the assembly interface and avoids a multi-domain transformation in the portion of the ferroelectric layer close to this interface.

The hydrogen concentration in the dielectric layer Diel can be reduced, for example, by way of a step of annealing the dielectric layer Diel aimed at bringing this dielectric layer to a temperature higher than that of the preparation heat treatment for the attached ferroelectric layer Ferro_{lay}, which will be subsequently described in this description. This layer thus can be brought to an annealing temperature of 600° C., 700° C., or even 800° C. or more. The average hydrogen concentration in the dielectric layer, after this exodiffusion step, thus can be less than 5.1020 at/cm³, or advantageously less than 10¹⁸ at/cm³.

With respect to the ferroelectric layer Ferro_{lay}, a preparation heat treatment can be applied thereto, followed by a thinning step.

The preparation heat treatment allows any crystalline defects present in the ferroelectric layer to be rectified. Furthermore, it helps to consolidate the bond between this ferroelectric layer Ferro_{lay} and the carrier Sprt. It also has the effect, if the temperature is high enough, of causing the diffusion of the hydrogen contained in the ferroelectric layer and the multi-domain transformation of a surface portion of this ferroelectric layer. The thickness of this surface portion can be of the order of 50 nm or less and can extend over the entire extent of the ferroelectric layer. On completion of the preparation heat treatment, the ferroelectric layer has a relatively constant hydrogen concentration throughout its thickness. In the case of LiTaO3, this preparation heat treatment is designed to bring the ferroelectric layer to a temperature ranging between 300° C. and the Curie temperature of the ferroelectric material (and preferably greater than or equal to 450° C., 500° C. or 550° C. in order to promote the hydrogen diffusion) for a duration ranging between 30 minutes and 10 hours. This heat treatment is preferably carried out by exposing the free face of the dielectric layer to an oxidizing or neutral gaseous atmosphere, i.e., without covering this face of the thin layer with a protective layer that could prevent the exodiffusion of the hydrogen.

Following the preparation heat treatment, the ferroelectric layer is thinned. This thinning can correspond to polishing the free face of the ferroelectric layer Ferro_{lay}, for example, using mechanical, chemical-mechanical thinning and/or chemical etching techniques. This allows the free face to be prepared so that it exhibits limited roughness, for example, less than 0.5 nm RMS 5×5 μm by atomic force measurement (AFM) and allows the multi-domain surface portion of the ferroelectric layer Ferro_{lay} to be removed. In general, a thickness of 100 to 300 nm is removed in order to achieve the target thickness of the ferroelectric layer Ferro_{lay}, and in all cases the thickness is greater than that of the multi-domain surface portion. Thus, a thin single-domain layer is formed with the required surface finish, crystalline quality and polarization qualities.

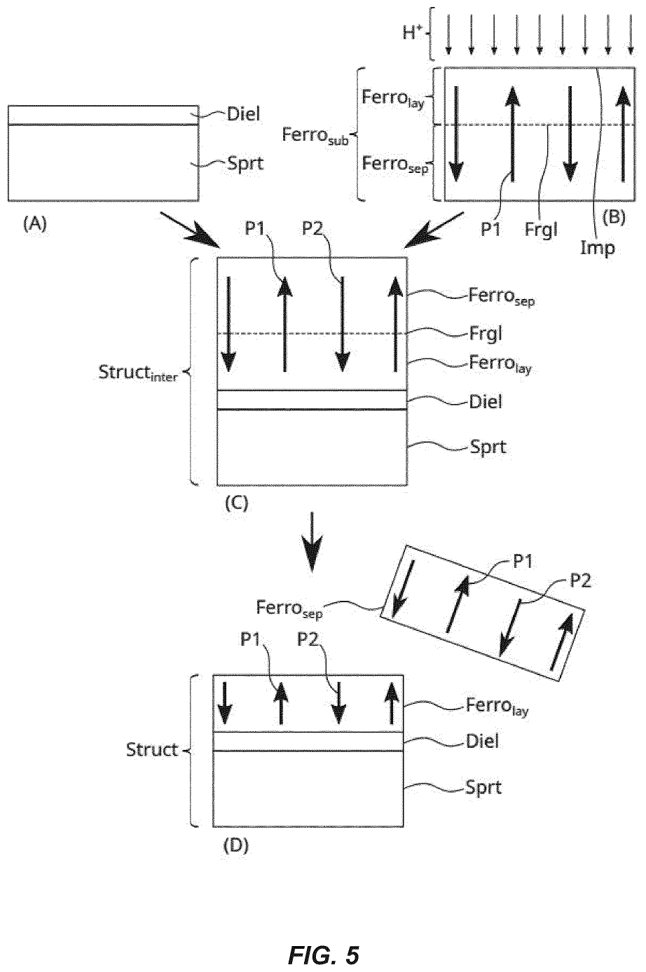

A selective polarization inversion as illustrated in FIGS. 1 to 3 applied to the structure Struct illustrated in section (D) of FIG. 4 allows the structure Struct illustrated in section (D) of FIG. 5 to be formed.

### Integration on a Carrier—Solution 2

Solution 1 illustrates a method for assembling a donor substrate Ferro_{sub} preferably having a first single-domain polarization P1 perpendicular to a flat face of the substrate. Subsequently, a selective polarization inversion can be applied to the ferroelectric layer Ferro_{lay} of the obtained structure Struct in order to achieve two vertical polarizations in opposite directions within this ferroelectric layer.

This section discloses an alternative solution 2 to solution 1 in that, instead of applying a selective polarization inversion after assembly, a selective polarization inversion is applied to a donor ferroelectric substrate prior to assembly, as illustrated in FIG. 5.

Thus, unless otherwise indicated, reference can be made to solution 1 for all the steps of the assembly method illustrated in FIG. 5, including the alternative of thinning the donor substrate Ferro_{sub} rather than fracturing the substrate. However, in this solution 2, the donor substrate Ferro_{sub} has two vertical polarizations P1 and P2 in opposite directions. Such a substrate can be obtained, for example, from a single-domain polarization substrate by selective polarization inversion, as illustrated in FIGS. 1 to 3, and from the associated manufacturing method.

### Example: Surface Acoustic Wave Device

By applying the selective polarization inversion method illustrated in FIGS. 1 to 3, so as to obtain a ferroelectric layer attached to a carrier and having two vertical polarizations P1 and P2 in opposite directions, as illustrated in section (D) of FIG. 5, it is possible, for example, to manufacture a surface acoustic wave device Dev_{SAW} from a ferroelectric layer whose polarization has been selectively modified.

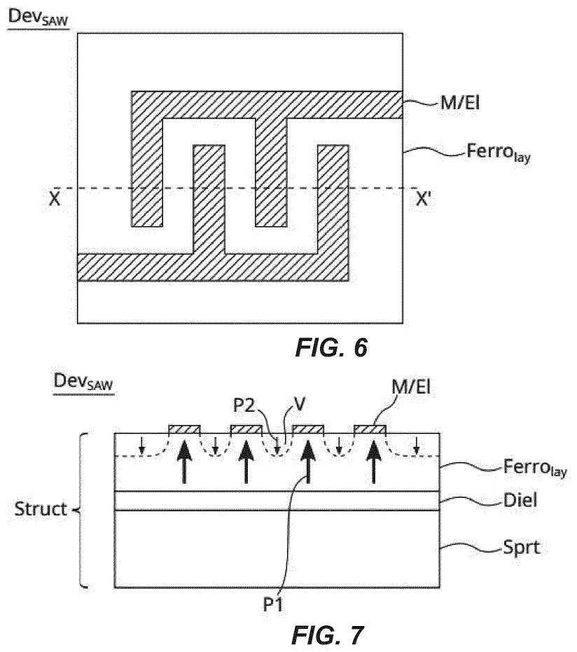

Such a device, illustrated by the plan view of FIG. 7 and by FIG. 7 illustrating a cross-sectional view along the XX′ axis of FIG. 6, conventionally comprises interdigitated electrodes formed directly on the ferroelectric layer Ferro_{lay}. Using these electrodes El as a mask M, then indicated as M/El in FIGS. 6 and 7, is advantageous during the selective introduction of hydrogen into the ferroelectric layer. Indeed, this method allows self-alignment of the inverted polarization volumes V with the interdigitated electrodes M/El. This yields the configuration indicated in section (C3) of FIG. 3. For the features and the method for manufacturing the elements of FIGS. 6 and 7, please refer to the descriptions of the elements in FIGS. 1 to 5.

It is worthwhile ensuring that the material for the electrodes is compatible with the annealing of step S20 intended to invert the first polarization P1 of the ferroelectric layer Ferro_{lay} in order to obtain a second polarization P2 opposite the first polarization P1 in the hydrogen-enriched volumes V.

In this document, the figures are not necessarily to scale. Some features and components may be shown enlarged relative to other components or in a somewhat schematic form, and some details of conventional elements may not be shown in the interest of clarity and conciseness.

Of course, the disclosure is not limited to the embodiments described, and alternative embodiments can be applied thereto without departing from the scope of the invention as defined by the claims.

1. A structure, comprising:
a ferroelectric layer having a first polarization in a first zone and a second polarization opposite the first polarization, in a second zone distinct from the first zone, wherein the first polarization and the second polarization are oriented perpendicularly or obliquely to the ferroelectric layer, the second zone having a higher hydrogen concentration than the first zone;
a carrier; and
a dielectric layer interposed between the carrier and the ferroelectric layer.

2. 1The structure of claim 1, wherein a hydrogen density in the second zone ranges between 10¹⁹ and 10²²atoms/cm³.

3. 2The structure of claim 1, wherein the first zone and the second zone define periodic patterns.

4. The structure of claim 1, wherein the ferroelectric layer is single-a single crystal.

5. The structure of claim 1, wherein the ferroelectric layer comprises lithium niobate or lithium tantalate.

6. The structure of claim 1, wherein the dielectric layer comprises silicon oxide.

7. The structure of claim 1, wherein the carrier comprises single-crystal silicon.

8. A method for manufacturing a ferroelectric element comprising:
providing a ferroelectric element having a first polarization;
selectively enriching the ferroelectric element with hydrogen ions through a face of the ferroelectric element; and
annealing the ferroelectric element after introducing the hydrogen ions, at a temperature ranging between 400° C. and 700° C., so as to switch the first polarization of the ferroelectric-layer element in a volume defined by the selective introduction of enrichment with the hydrogen ions.

9. The method of claim 8, wherein the first polarization is mono-domain, perpendicular or oblique with respect to a face of the ferroelectric element.

10. The method of claim 8, wherein the selectively enriching the ferroelectric element with the hydrogen ions is implemented by ion implantation of the hydrogen ions through a mask defining a region of the ferroelectric element not receiving hydrogen ions.

11. The method of claim 10, wherein the ion implantation of the hydrogen ions is implemented at an energy level ranging between 3 keV and 210 keV.

12. The method of claim 8, wherein the selective enrichment with the hydrogen ions is provided by elements intended to form part of a surface acoustic wave device.

13. The method of claim 8, wherein the ferroelectric element is a lithium niobate or lithium tantalate layer.

14. The method of claim 8, further comprising assembling a ferroelectric substrate and a carrier, followed by separating or thinning the ferroelectric substrate so as to define the ferroelectric element.

15. The method of claim 14, further comprising selecting the carrier to comprise a single-crystal silicon substrate, and providing a dielectric layer comprising silicon oxide between the single-crystal silicon substrate and the ferroelectric substrate.

16. The method of claim 8, further comprising selecting a dose of the hydrogen ions in the selectively enriching the ferroelectric element with the hydrogen ions so as to obtain a hydrogen density ranging between 10¹⁹ and 10²² atoms/cm³ in volume.

17. The structure of claim 2, wherein the first zone and the second zone define periodic patterns.

18. The structure of claim 17, wherein the ferroelectric layer is a single crystal.

19. The structure of claim 18, wherein the ferroelectric layer comprises lithium niobate or lithium tantalate.

20. The structure of claim 19, wherein the dielectric layer comprises silicon oxide.
